(19) United States
(12) Patent Application Publication
(10) Pub. No.: US 2005/0135071 A1
(43) Pub. Date: Jun. 23, 2005

(54) Package structure of optical sensitive device and method for packaging optical sensitive device

(75) Inventors: Billy Wang, Hsin Chu City (TW); Bill Chang, Hsin Chu City (TW); Yu-Jen Huang, Tai Chung City (TW); Chao-Yen Hsieh, Tai Chung Hsien (TW)

Correspondence Address: TROXELL LAW OFFICE PLLC, SUITE 1404, 5205 LEESBURG PIKE, FALLS CHURCH, VA, 22041, US

(73) Assignee: Harvatek Corporation

(21) Appl. No.: 10/737,808

(22) Filed: Dec. 18, 2003

(51) Int. Cl. H05K 1/14

(52) U.S. Cl. 361/737

(57) ABSTRACT

The present invention provides a package structure of optical sensitive device. The package structure includes a silicon substrate, an optical sensitive device, a supporting pad, a transparent plate and a plurality of conductive wires. The optical sensitive device is positioned on the silicon substrate, and the transparent plate is fixedly positioned on the supporting pad and corresponds to the optical sensitive area of the optical sensitive device. The transparent plate can be positioned on the substrate, and the electrical wires are electrically connected between the optical sensitive device and the substrate. A molding material is applied the periphery of the optical sensitive device and the substrate to prevent the electrical wires from exposed and damaged, thereby resulting in virtually eliminating particle containment

### BACKGROUND OF THE INVENTION

1. Field of the Invention

The present invention relates to a package structure of optical sensitive device and a method of packaging optical sensitive device, and in particular to a method used to package optical sensitive device by package process.

2. Description of Related Art

FIG. 1 illustrates a package structure of an optical sensitive device after wafer package process in prior art is performed. A plurality of optical sensitive devices are fabricated on a silicon wafer (not shown), and the silicon wafer is cut into several separate optical sensitive devices 10a (becomes singulated) via wafer dicing process. A supporting pad 30a is attached to a printed circuit board (PCB) substrate 20a so that a cavity 21a is provided. Then, the optical sensitive device 10a is positioned on the cavity 21a of the PCB substrate 20a by adhesive, and the adhesive is heated to solidify. Wire bonding is performed on the optical sensitive device 10a, and adhesive is applied to the supporting pad 30a which is covered with a glass plate 40a. However, there are some shortcomings in the conventional optical sensitive device as described below:
1. The conventional package process is performed after a plurality of optical sensitive devices are fabricated on a silicon wafer. The conventional package process includes wafer dicing, applying adhesive and wire bonding to package the optical sensitive devices. In this regard, it is likely for particles to adhere to the optical sensitive area of the optical sensitive devices during package process. Purification of processing environment (or cleanroom) is strictly required, so cost of packaging is increased significantly.
2. The package structure of conventional optical sensitive device is bulky because the volume of the supporting pad is large, thereby resulting in increasing cost of packaging and limiting the optical sensitive device applications.

Thus, there is need to development for a method to package an optical sensitive device without particle contamination.

### SUMMARY OF THE DISCLOSURE

It is an object of the present invention to provide a package structure of an optical sensitive device and a method of packaging optical sensitive device. The method in accordance with the present invention packages an optical sensitive area of the optical sensitive device at an early stage in the package process, thereby resulting in virtually eliminating particle containment and requiring lower purification of processing environment so as to decrease cost of packaging.

It is another object of the present invention to provide a package structure of optical sensitive device and a method of packaging optical sensitive device. The method of the present invention has volume of a supporting pad to be decreased, so volume of package structure of the optical sensitive device is decreased.

In order to accomplish the object of the present invention, the present invention provides a package structure of optical sensitive device. According to the present invention, the package structure includes a silicon substrate, an optical sensitive device, a supporting pad, a transparent plate and a plurality of conductive wires. The optical sensitive device has an optical sensitive area and a plurality of bonding pads, and the optical sensitive device is positioned on the silicon substrate. The supporting pads are provided around the periphery of the optical sensitive area, and the transparent plate is fixedly positioned on the supporting pad and corresponds to the optical sensitive area of the optical sensitive device. In addition, the conductive wires are respectively electrically connected between the bonding pads of the optical sensitive device and the substrate.

In order to accomplish the object of the present invention, the present invention provides a method of packaging optical sensitive device. The method according to the present invention, comprising:
fabricating a plurality of optical sensitive devices on a silicon wafer, and each of the optical sensitive devices having an optical sensitive area and a plurality of bonding pads;
positioning a plurality of separate supporting pads on the silicon wafer, and each of the supporting pads positioned around the supporting pad and corresponding to the optical sensitive area;
positioning a plurality of transparent plates on the supporting pads, and the transparent plates corresponding to the optical sensitive areas; and
cutting the silicon wafer and obtaining separate optical sensitive devices.

Thus, the present invention virtually eliminates particle containment on the optical sensitive devices and has the volume of the package structure of the optical sensitive devices to be decreased.

### BRIEF DESCRIPTION OF DRAWINGS

The present invention can be fully understood from the following detailed description and preferred embodiment with reference to the accompanying drawings in which:

FIG. 1 is a cross-sectional view of a package structure of a conventional optical sensitive device;

FIG. 2 is a cross-sectional view of a package structure of an optical sensitive device in accordance with the present invention;

FIG. 3 is a top plan view of a silicon wafer including a plurality of the optical sensitive device in accordance with the present invention;

FIG. 3A is an enlarged top plan view of the optical sensitive device indicated by arrow A of FIG. 2;

FIG. 4 is a top plan view of the optical sensitive device of FIG. 3 with a supporting pad mounted;

FIG. 5 is a cross-sectional view of the silicon wafer of FIG. 3;

FIG. 6 is a cross-sectional view of the silicon wafer of FIG. 3 with transparent plates mounted;

FIG. 7 is a cross-sectional view of a package structure in accordance with the present invention when the optical sensitive device is positioned on the silicon wafer;

FIG. 8 is a cross-sectional view of the present invention of FIG. 7; and

FIG. 9 is a cross-sectional view of the present invention of FIG. 8 with electrical wires connected between the optical sensitive device and the silicon wafer.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

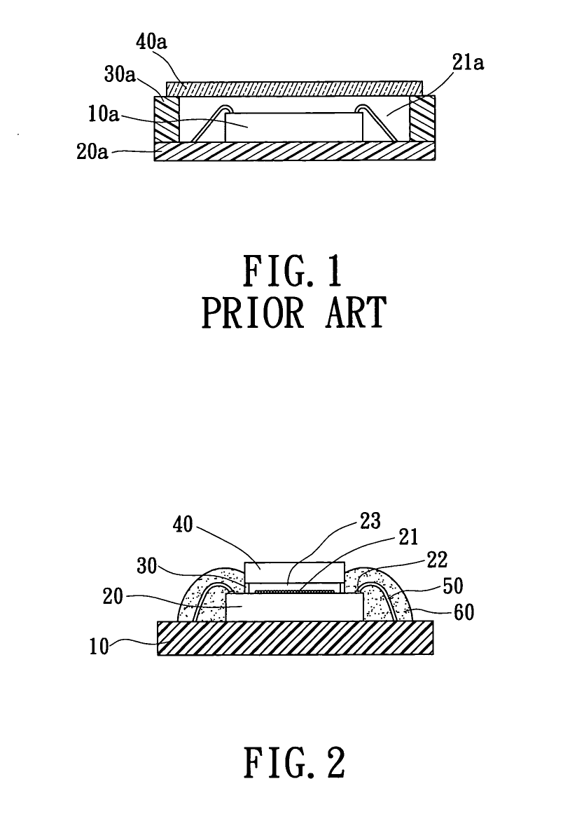

Referring to FIG. 2, a package structure of the present invention includes a substrate 10, an optical sensitive device 20, supporting pads 30, a transparent plate 40 and electrical wires 50. The substrate 10 can be a printed circuit board (PCB). The optical sensitive device 20 has an optical sensitive area 21 and bonding pads 22, and the bonding pads 22 are positioned near the edges of the optical sensitive device 20. The supporting pads 30 are positioned around the optical sensitive area 21 of the optical sensitive device 20. The transparent plate 40 is fixedly positioned on the supporting pads 30 and corresponds to the optical sensitive area 21. The transparent plate 40 can be, but not limited to a glass plate or a transparent resin plate. The transparent plate 40, the supporting pads 30 and optical sensitive area 21 of the optical sensitive device 20 are used to form a cavity 23. In addition, the electrical wires 50 are electrically connected between the bonding pads 22 and the substrate 10. A molding material 60 (i.e. Epoxy) is applied the periphery of the optical sensitive device 20 and the substrate 10 to prevent the electrical wires 50 from exposed and damaged. Thus, the package structure with small footprint is achieved.

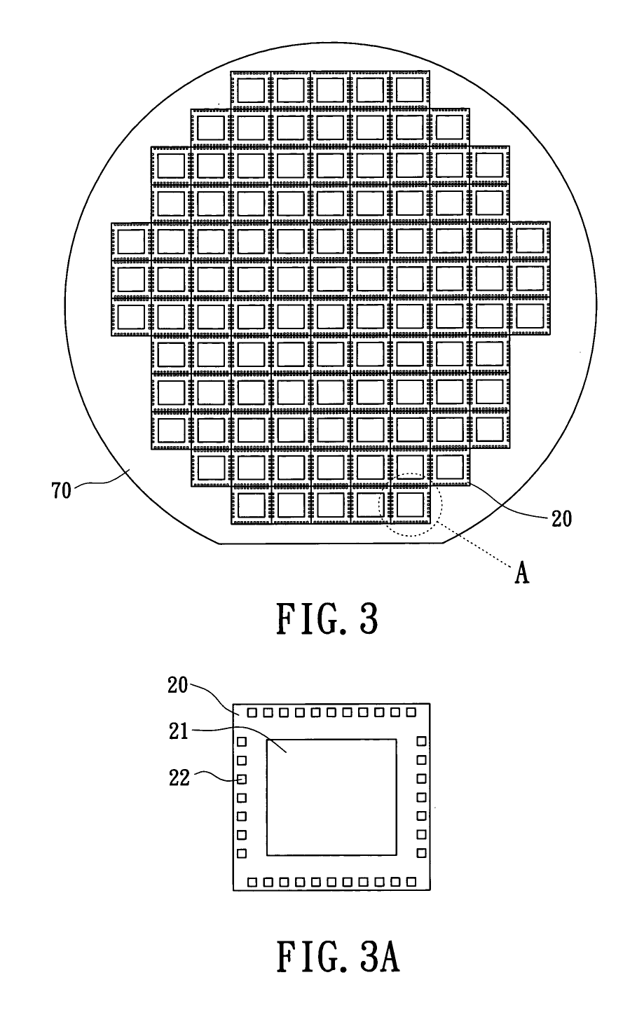

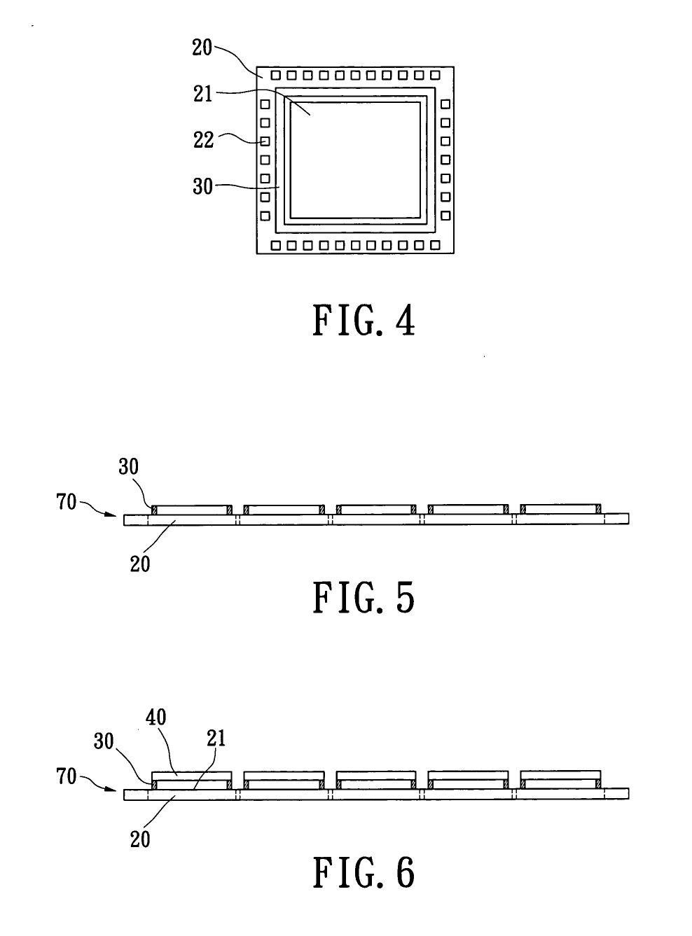

FIGS. 3-9 illustrate how to fabricate the package structure of the optical sensitive device in accordance with the present invention. Referring to FIGS. 3 and 3A, a plurality of optical sensitive devices 20 are fabricated on a silicon wafer 70. As described above, each of the optical sensitive devices 20 has an optical sensitive area 21 and bonding pads 22. As shown in FIGS. 4 and 5, the supporting pads 30 are separately positioned on the silicon wafer 70 and can be UV curable adhesive or thermosetting resin. The supporting pads 30 are positioned near and correspond to the periphery of the optical sensitive area 21.

Referring to FIG. 6, the transparent plates 40 are respectively positioned on the supporting pads 30 and correspond to the optical sensitive area 21. Then, the supporting pads 30 which are made of UV curable adhesives are subjected to ultra-violet ray so that the supporting pads 30 are fixedly attached to the optical sensitive devices 20 and the transparent plates 40.

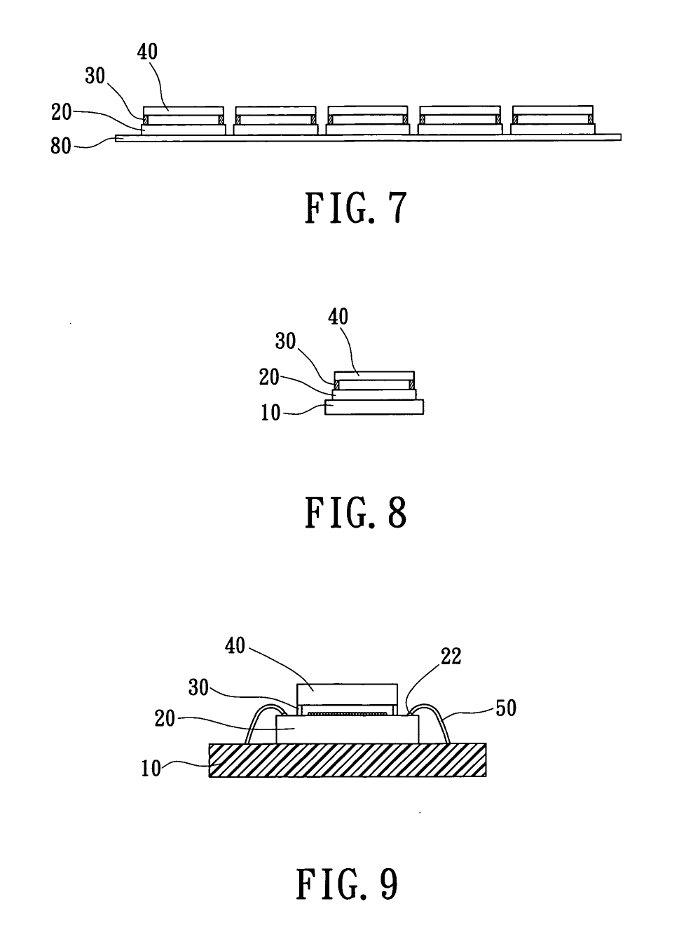

Referring to FIG. 7, an adhesive layer 80 is attached to the bottom of the silicon wafer 70, and the silicon wafer 70 is cut into several separate optical sensitive devices 20 via wafer dicing process. Then, the adhesive layer 80 is forcedly separated from the optical sensitive devices 20, and the optical sensitive devices 20 is attached to the substrate 10 as shown in FIG. 8.

Referring to FIG. 9, the electrical wires 50 are electrically connected between the bonding pads 22 and the substrate 10. As shown in FIG. 2, the molding material 60 is applied the periphery of the optical sensitive device 20 and the substrate 10 so that the optical sensitive area 21 of the optical sensitive devices 20 is encapsulated by the supporting pads 30 and the transparent plates 40. Thus, it results in virtually eliminating particle containment and requiring lower purification of processing environment so as to decrease cost of packaging.

While the invention has been described with reference to the preferred embodiments, the description is not intended to be construed in a limiting sense. It is therefore contemplated that the appended claims will cover any such modifications or embodiments as may fall within the scope of the invention defined by the following claims and their equivalents.

1. A package structure of an optical sensitive device, comprising:
a substrate;
an optical sensitive device, positioned on the substrate and having an optical sensitive area and bonding pads;
at least one supporting pad, positioned around the optical sensitive area of the optical sensitive device;
a transparent plate, fixedly positioned on the at least one supporting pad and corresponding to the optical sensitive area; and
a plurality of electrical wires, electrically connected between the bonding pads and the substrate.

2. The package structure as claimed in claim 1, further comprising a molding material which is applied the periphery of the optical sensitive device and the substrate to encapsulate the electrical wires.

3. The package structure as claimed in claim 2, wherein the molding material is made of epoxy.

4. The package structure as claimed in claim 1, wherein the transparent plate is fixedly positioned on the supporting pad to cover the optical sensitive area of the optical sensitive device so that the transparent plate, the supporting pad and optical sensitive area of the optical sensitive device are used to form a cavity.

5. The package structure as claimed in claim 1, wherein the transparent plate is a glass plate.

6. The package structure as claimed in claim 1, wherein the transparent plate is a transparent resin plate.

7. The package structure as claimed in claim 1, wherein the supporting pad is made of thermosetting resin.

8. The package structure as claimed in claim 1, wherein the supporting pad is made of UV curable adhesive.

9. A package structure of an optical sensitive device, comprising:
an optical sensitive device, having an optical sensitive area;
at least one supporting pad, positioned around the optical sensitive area of the optical sensitive device; and
a transparent plate, fixedly positioned on the at least one supporting pad to cover the optical sensitive area.

10. The package structure as claimed in claim 9, further comprising a plurality of supporting pads, a plurality of electrical wires and a substrate, wherein the supporting pads are provided around the periphery of the optical sensitive area and the electrical wires are electrically connected between the bonding pads and the substrate.

11. The package structure as claimed in claim 10, further comprising a molding material which is applied the periphery of the optical sensitive device and the substrate to encapsulate the electrical wires.

12. The package structure as claimed in claim 9, wherein the transparent plate is fixedly positioned on the supporting pad to cover the optical sensitive area of the optical sensitive device so that the transparent plate, the supporting pad and optical sensitive area of the optical sensitive device are used to form a cavity.

13. The package structure as claimed in claim 9, wherein the transparent plate is a glass plate.

14. The package structure as claimed in claim 9, wherein the supporting pad is made of UV curable adhesive.

15. The package structure as claimed in claim 9, wherein the supporting pad is made of thermosetting resin.

16. The package structure as claimed in claim 9, wherein the supporting pad is made of UV curable adhesive.

17. The method of packaging optical sensitive device, comprising:
fabricating a plurality of optical sensitive devices on a silicon wafer, and each of the optical sensitive devices having an optical sensitive area and
a plurality of bonding pads;
positioning a plurality of separate supporting pads on the silicon wafer, and each of the supporting pads positioned around the supporting pad and corresponding to the optical sensitive area;
positioning a plurality of transparent plates on the supporting pads, and the transparent plates corresponding to the optical sensitive areas; and
cutting the silicon wafer and obtaining separate optical sensitive devices.

18. The method of packaging optical sensitive device as claimed in claim 17, further comprising:
attaching the optical sensitive device to the silicon wafer, and being electrically connected between the bonding pads and the substrate.

19. The method of packaging optical sensitive device as claimed in claim 18, further comprising a molding material which is applied the periphery of the optical sensitive device and the substrate to encapsulate the electrical wires.

20. The method of packaging optical sensitive device as claimed in claim 19, wherein the molding material is made of epoxy.

21. The method of packaging optical sensitive device as claimed in claim 17, wherein the supporting pad is made of UV curable adhesive.

22. The method of packaging optical sensitive device as claimed in claim 17, wherein the transparent plates are respectively positioned on the supporting pads and the supporting pads 30 which are made of UV curable adhesives are subjected to ultra-violet ray so that the supporting pads are fixedly attached to the optical sensitive devices and the transparent plates.

23. The method of packaging optical sensitive device as claimed in claim 17, wherein the supporting pad is made of thermosetting resin.

24. The method of packaging optical sensitive device as claimed in claim 17, wherein the transparent plate is fixedly positioned on the supporting pad to cover the optical sensitive area of the optical sensitive device so that the transparent plate, the supporting pad and optical sensitive area of the optical sensitive device are used to form a cavity.

25. The method of packaging optical sensitive device as claimed in claim 17, wherein the transparent plate is a glass plate.

26. The method of packaging optical sensitive device as claimed in claim 17, wherein the transparent plate is a transparent resin plate.
